(19) United States
(12) Patent Application Publication
(10) Pub. No.: US 2026/0047400 A1
(43) Pub. Date: Feb. 12, 2026

(54) TEST STRUCTURE

(71) Applicant: Winbond Electronics Corp., Taichung City (TW)

(72) Inventors: Jun-Jie Pang, Taichung City (TW); Shih-Ming Wang, Tainan City (TW)

(73) Assignee: Winbond Electronics Corp., Taichung City (TW)

(21) Appl. No.: 19/262,103

(22) Filed: Jul. 8, 2025

(30) Foreign Application Priority Data
Aug. 9, 2024 (TW) 113129888

(51) Int. Cl. H01L 21/66; H10B 12/00

(52) U.S. Cl. CPC H01L 22/32; H10B 12/488

(57) ABSTRACT

A test structure includes at least one test element. The test element includes a substrate, an isolation structure, and multiple word lines. The isolation structure is located in the substrate. The isolation structure defines multiple active regions in the substrate. The word lines include multiple first word lines and multiple second word lines that are alternately arranged. The first word lines are located in the active regions. The second word lines are not located in the active regions and are located on the isolation structure. The first word lines and the second word lines are insulated from the substrate.

### CROSS-REFERENCE TO RELATED APPLICATION

This application claims the priority benefit of Taiwan application serial no. 113129888, filed on Aug. 9, 2024. The entirety of the above-mentioned patent application is hereby incorporated by reference herein and made a part of this specification.

### BACKGROUND

### Technical Field

The disclosure relates to a semiconductor structure, and particularly relates to a test structure.

### Description of Related Art

Currently, a test structure is used to measure a resistance of a word line located on an active region and a resistance of a word line located on an isolation structure. However, how to accurately measure the resistance of the word line located on the active region and the resistance of the word line located on the isolation structure is currently a goal of continuous efforts.

### SUMMARY

The disclosure provides a test structure that can accurately measure a resistance of a word line located on an active region and a resistance of a word line located on an isolation structure.

The disclosure provides a test structure that includes at least one test element. The test element includes a substrate, an isolation structure, and multiple word lines. The isolation structure is located in the substrate. The isolation structure defines multiple active regions in the substrate. The word lines include multiple first word lines and multiple second word lines that are alternately arranged. The first word lines are located in the active regions. The second word lines are not located in the active regions and are located on the isolation structure. The first word lines and the second word lines are insulated from the substrate.

Based on the above, in the test structure proposed by the disclosure, the word lines include the first word lines and the second word lines that are alternately arranged. The first word lines are located in the active regions, and the second word lines are not located in the active regions and are located on the isolation structure to allow an environment of the word lines to be closer to an environment of an array area in a chip. Therefore, a resistance of the first word lines located on the active regions and a resistance of the second word lines located on the isolation structure may be more accurately measured. In addition, whether there is a mismatch problem in resistances of different first word lines may be checked by measuring the resistances of the different first word lines. If the resistances of the different first word lines do not match, it is indicated that there might be a problem in a relevant process of the word lines in the active regions of the array area in the chip, so that a process problem may be found and solved. In addition, whether there is a mismatch problem in resistances of different second word lines may be checked by measuring the resistances of the different second word lines. If the resistances of the different second word lines do not match, it is indicated that there might be a problem in a relevant process of the word lines in the isolation structure of the array area in the chip, so that a process problem may be found and solved.

In order to make the features and advantages of the disclosure more comprehensible, the following examples are given and described in detail with the accompanying drawings as follows.

### BRIEF DESCRIPTION OF THE DRAWINGS

FIG. 1 is a top view of a test structure according to some embodiments of the disclosure.

FIG. 2 is a top view of a test structure according to other embodiments of the disclosure.

### DESCRIPTION OF THE EMBODIMENTS

The embodiments are described in detail below with reference to the accompanying drawings, but the embodiments are not intended to limit the scope of the disclosure. For ease of understanding, the same elements in the following description are denoted by the same reference symbols. In addition, the drawings are for illustrative purposes only and are not drawn to the original dimensions. In fact, the dimensions of the various features may be arbitrarily increased or reduced for clarity of discussion.

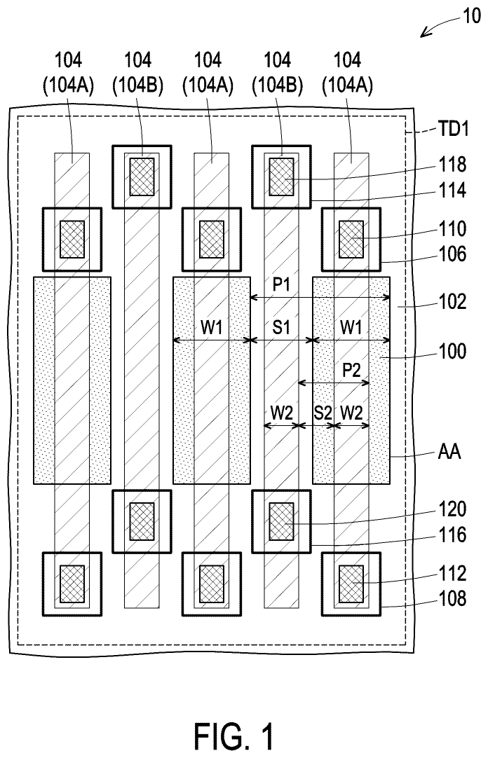

FIG. 1 is a top view of a test structure according to some embodiments of the disclosure.

Please refer to FIG. 1. A test structure 10 includes at least one test element TD1. In the embodiment, the quantity of the test element TD1 is one as an example for descriptions, but the disclosure is not limited thereto. As long as the quantity of the test element TD1 is at least one, it falls within the scope of the disclosure.

The test element TD1 includes a substrate 100, an isolation structure 102, and multiple word lines 104. In some embodiments, the test structure 10 may be a test key structure. In some embodiments, the test structure 10 may be configured to test the element characteristics in a chip. For example, the test structure 10 may be configured to test the element characteristics of dynamic random access memory (DRAM) in the chip. In some embodiments, the test structure 10 may be located in a scribe lane region of a wafer and not located in a die region of the wafer. In other embodiments, the test structure 10 may be made into a module test key and independently divide into a die region. In other embodiments, the test structure 10 may be located in a test area of a die region. In some embodiments, the substrate 100 may be a semiconductor substrate, such as a silicon substrate.

The isolation structure 102 is located in the substrate 100. The isolation structure 102 defines multiple active regions AA in the substrate 100. In some embodiments, a width W1 of the active regions AA may be the same. In some embodiments, the isolation structure 102 is, for example, a shallow trench isolation (STI) structure. In some embodiments, the material of the isolation structure 102 is, for example, an oxide (such as silicon oxide).

Multiple word lines 104 include multiple word lines 104A and multiple word lines 104B that are alternately arranged. In some embodiments, a width W2 of the word lines 104 may be the same. In some embodiments, a pitch P1 of the active regions AA may be larger than a pitch P2 of the word lines 104. In some embodiments, the pitch P1 of the active regions AA may be twice the pitch P2 of the word lines 104. In some embodiments, a pitch may be defined as a sum of a line width and a line spacing. For example, as shown in FIG. 1, the pitch P1 may be a sum of the width W1 of the active region AA and a distance S1 between the active regions AA, and the pitch P2 may be a sum of the width W2 of the word line 104 and a distance S2 between the word lines 104.

In some embodiments, the word lines 104 may be embedded word lines. In some embodiments, the embedded word lines may be word lines that are embedded in the substrate 100 and/or the isolation structure 102. In some embodiments, the word lines 104 may be planar word lines. In some embodiments, the planar word lines may be word lines that are located on a top surface of the substrate 100 and/or a top surface of the isolation structure 102. In some embodiments, in a condition where the dimension of the test structure 10 continues to shrink, the word lines 104 may be formed by a litho-etch-litho-etch (LELE) process or a self-aligned double patterning (SADP) process. In some embodiments, the word lines 104 may be a multi-layer stack structure that includes a barrier layer and a conductive layer.

The word lines 104A are located in the active regions AA. In some embodiments, the word lines 104A may further be located in an exterior of the active regions AA. In some embodiments, the word lines 104A may further be located on the isolation structure 102. In some embodiments, an orthographic projection of the word lines 104A may be located on the active regions AA. In some embodiments, the orthographic projection of the word lines 104A may further be located on the isolation structure 102. In some embodiments, the width W1 of the active regions AA may be greater than the width W2 of the word lines 104A. In some embodiments, the material of the word lines 104A is, for example, metal (such as tungsten or titanium), titanium nitride, doped polysilicon, or a combination thereof.

The word lines 104B are not located in the active regions AA and are located on the isolation structure 102. In some embodiments, an orthographic projection of the word lines 104B may be completely located on the isolation structure 102. In some embodiments, the width W1 of the active regions AA may be greater than the width W2 of the word lines 104B. In some embodiments, the material of the word lines 104B is, for example, metal (such as tungsten or titanium), titanium nitride, or doped polysilicon, or a combination thereof.

The word lines 104A and the word lines 104B are insulated from the substrate 100. For example, the word lines 104A may be insulated from the substrate 100 by a dielectric layer (not shown) and the isolation structure 102. In addition, the word lines 104B may be insulated from the substrate 100 by the isolation structure 102.

The test structure 10 may further include multiple wires 106, multiple wires 108, multiple contacts 110, multiple contacts 112, multiple wires 114, multiple wires 116, multiple contacts 118, and multiple contacts 120. The wires 106 and the wires 108 are located on opposite sides of the active regions AA. The wires 106 and the wires 108 are electrically connected to the word lines 104A. Therefore, a current and a voltage of the word lines 104A located on the active regions AA may be measured by the wires 106 and the wires 108 to obtain a resistance of the word lines 104A located on the active regions AA. In some embodiments, the wires 106 and the wires 108 may be a single-layer structure or a multi-layer structure. In some embodiments, the material of the wires 106 and the wires 108 is, for example, tungsten, aluminum, copper, titanium, titanium nitride, tantalum, tantalum nitride, or a combination thereof.

The contacts 110 are located between the wires 106 and the word lines 104A. The contacts 110 are electrically connected to the wires 106 and the word lines 104A. The contacts 112 are located between the wires 108 and the word lines 104A. The contacts 112 are electrically connected to the wires 108 and the word lines 104A. In some embodiments, the contacts 110 and the contacts 112 may be a single-layer structure or a multi-layer structure. In some embodiments, the material of the contacts 110 and the contacts 112 is, for example, tungsten, titanium, titanium nitride, or a combination thereof.

The wires 114 and the wires 116 are located on opposite sides of the active regions AA. The wires 114 and the wires 116 are electrically connected to the word lines 104B. Therefore, a current and a voltage of the word lines 104B located on the isolation structure 102 may be measured by the wires 114 and the wires 116 to obtain a resistance of the word lines 104B located on the isolation structure 102. In some embodiments, the wires 114 and the wires 116 may be a single-layer structure or a multi-layer structure. In some embodiments, the material of the wires 114 and the wires 116 is, for example, tungsten, aluminum, copper, titanium, titanium nitride, tantalum, tantalum nitride, or a combination thereof.

The contacts 118 are located between the wires 114 and the word lines 104B. The contacts 118 are electrically connected to the wires 114 and the word lines 104B. The contacts 120 are located between the wires 116 and the word lines 104B. The contacts 120 are electrically connected to the wires 116 and the word lines 104B. In some embodiments, the contacts 118 and the contacts 120 may be a single-layer structure or a multi-layer structure. In some embodiments, the materials of the contacts 118 and the contacts 120 is, for example, tungsten, titanium, titanium nitride, or a combination thereof.

The wires 106 and the wires 114 may be located on the same side of the active regions AA, and positions of the wires 106 and positions of the wires 114 may be different, but the disclosure is not limited thereto. Since the positions of the wires 106 and the positions of the wires 114 may be different and arranged in a staggered manner, the layout design of the wires 106 and the wires 114 may be more flexible to allow the wires 106 and the wires 114 to be applied in a semiconductor element with a smaller dimension. In other embodiments, the wires 106 and the wires 114 may be located on the same side of the active regions AA, and the positions of the wires 106 and the positions of the wires 114 may be the same.

The wires 108 and the wires 116 may be located on the same side of the active regions AA, and positions of the wires 108 and positions of the wires 116 may be different, but the disclosure is not limited thereto. Since the positions of the wires 108 and the positions of the wires 116 may be different and arranged in a staggered manner, the layout design of the wires 108 and the wires 116 may be more flexible to allow the wires 108 and the wires 116 to be applied in a semiconductor element with a smaller dimension. In other embodiments, the wires 108 and the wires 116 may be located on the same side of the active regions AA, and the positions of the wires 108 and the positions of the wires 116 may be the same.

Based on the above embodiments, it may be known that in the test structure 10, the word lines 104 include the word lines 104A and the word lines 104B that are alternately arranged. The word lines 104A are located in the active regions AA, and the word lines 104B are not located in the active regions AA and are located on the isolation structure 102 to allow an environment of the word lines 104 to be closer to an environment of an array area in a chip. Therefore, a resistance of the word lines 104A located on the active regions AA and a resistance of the word lines 104B located on the isolation structure 102 may be more accurately measured. In addition, whether there is a mismatch problem in resistances of different word lines 104A may be checked by measuring the resistances of the different word lines 104A. If the resistances of the different word lines 104A do not match, it is indicated that there might be a problem in a relevant process of the word lines in the active regions of the array area in the chip, so that a process problem to be found and solved. In addition, whether there is a mismatch problem in resistances of different word lines 104B may be checked by measuring the resistances of the different word lines 104B. If the resistances of the different word lines 104B do not match, it is indicated that there might be a problem in a relevant process of the word lines in the isolation structure of the array area in the chip, so that a process problem may be found and solved.

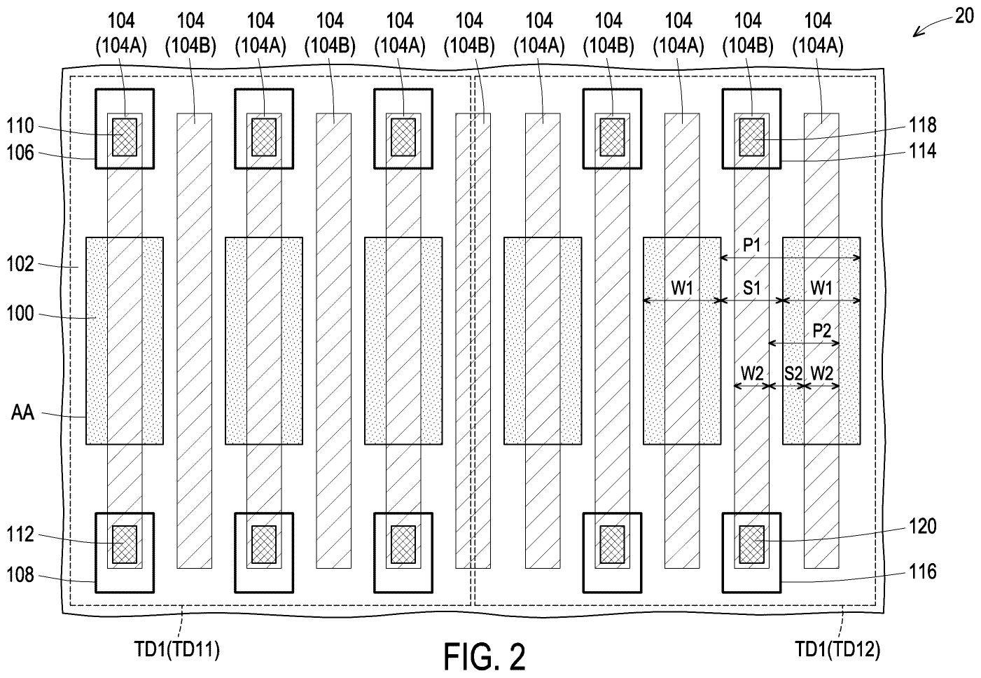

FIG. 2 is a top view of a test structure according to other embodiments of the disclosure.

Please refer to FIG. 1 and FIG. 2. The same or similar components are denoted by the same reference numerals, and descriptions thereof are omitted. In a test structure 20 of FIG. 2, the at least one test element TD1 may include a test element TD11 and a test element TD12. In the test element TD11, the wires 106 and the wires 108 are located on opposite sides of the active regions AA of the test element TD11, and the wires 106 and the wires 108 are electrically connected to the word lines 104A of the test element TD11. In addition, the word lines 104B of the test element TD11 are not electrically connected to any wire.

In the test element TD12, the wires 114 and the wires 116 are located on opposite sides of the active regions AA of the test element TD12, and the wires 114 and the wires 116 are electrically connected to the word lines 104B of the test element TD12. In addition, the word lines 104A of the test element TD12 are not electrically connected to any wire.

Based on the above embodiments, it may be known that in the test structure 20, the word lines 104 include the word lines 104A and the word lines 104B that are alternately arranged. The word lines 104A are located in the active regions AA, and the word lines 104B are not located in the active regions AA and are located on the isolation structure 102 to allow the environment of the word lines 104 to be closer to the environment of the array area. Therefore, a resistance of the word lines 104A located on the active regions AA and a resistance of the word lines 104B located on the isolation structure 102 may be more accurately measured. In addition, whether there is a mismatch problem in resistances of different word lines 104A may be checked by measuring the resistances of the different word lines 104A. If the resistances of the different word lines 104A do not match, it is indicated that there might be a problem in a relevant process of the word lines in the active regions of the array area in the chip, so that a process problem may be found and solved. In addition, whether there is a mismatch problem in resistances of different word lines 104B may be checked by measuring the resistances of the different word lines 104B. If the resistances of the different word lines 104B do not match, it is indicated that there might be a problem in a relevant process of the word lines in the isolation structure of the array area in the chip, so that a process problem may be found and solved.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A test structure, comprising at least one test element, wherein the at least one test element comprises:
a substrate;
an isolation structure, located in the substrate, wherein the isolation structure defines a plurality of active regions in the substrate; and
a plurality of word lines, comprising a plurality of first word lines and a plurality of second word lines that are alternately arranged, wherein
the first word lines are located in the active regions, and
the second word lines are not located in the active regions and are located on the isolation structure, and
the first word lines and the second word lines are insulated from the substrate.

2. The test structure according to claim 1, wherein the first word lines are further located in an exterior of the active regions.

3. The test structure according to claim 1, wherein the first word lines are further located on the isolation structure.

4. The test structure according to claim 1, wherein an orthographic projection of the first word lines is located on the active regions.

5. The test structure according to claim 4, wherein the orthographic projection of the first word lines is further located on the isolation structure.

6. The test structure according to claim 1, wherein an orthographic projection of the second word lines is completely located on the isolation structure.

7. The test structure according to claim 1, wherein a width of the active regions is greater than a width of the first word lines.

8. The test structure according to claim 1, wherein a width of the active regions is greater than a width of the second word lines.

9. The test structure according to claim 1, wherein a pitch of the active regions is greater than a pitch of the word lines.

10. The test structure according to claim 1, wherein a pitch of the active regions is twice a pitch of the word lines.

11. The test structure according to claim 1, further comprising:
a plurality of first wires and a plurality of second wires, located on opposite sides of the active regions, and electrically connected to the first word lines; and
a plurality of third wires and a plurality of fourth wires, located on opposite sides of the active regions, and electrically connected to the second word lines.

12. The test structure according to claim 11, wherein the first wires and the third wires are located on a same side of the active regions, and positions of the first wires and positions of the third wires are different.

13. The test structure according to claim 11, wherein the second wires and the fourth wires are located on a same side of the active regions, and positions of the second wires and positions of the fourth wires are different.

14. The test structure according to claim 11, further comprising:
a plurality of first contacts, located between the first wires and the first word lines, and electrically connected to the first wires and the first word lines;
a plurality of second contacts, located between the second wires and the first word lines, and electrically connected to the second wires and the first word lines;
a plurality of third contacts, located between the third wires and the second word lines, and electrically connected to the third wires and the second word lines; and
a plurality of fourth contacts, located between the fourth wires and the second word lines, and electrically connected to the fourth wires and the second word lines.

15. The test structure according to claim 1, wherein the at least one test element comprises a first test element and a second test element.

16. The test structure according to claim 15, further comprising:
a plurality of first wires and a plurality of second wires, located on opposite sides of the active regions of the first test element, and electrically connected to the first word lines of the first test element; and
a plurality of third wires and a plurality of fourth wires, located on opposite sides of the active regions of the second test element, and electrically connected to the second word lines of the second test element.

17. The test structure according to claim 16, further comprising:
a plurality of first contacts, located between the first wires and the first word lines, and electrically connected to the first wires and the first word lines;
a plurality of second contacts, located between the second wires and the first word lines, and electrically connected to the second wires and the first word lines;
a plurality of third contacts, located between the third wires and the second word lines, and electrically connected to the third wires and the second word lines; and
a plurality of fourth contacts, located between the fourth wires and the second word lines, and electrically connected to the fourth wires and the second word lines.

18. The test structure according to claim 16, wherein the second word lines of the first test element are not electrically connected to any wire, and the first word lines of the second test element are not electrically connected to any wire.

19. The test structure according to claim 1, wherein the word lines comprise an embedded word line.

20. The test structure according to claim 1, wherein the word lines comprise a planar word line.
